(19) United States
(12) Patent Application Publication
(10) Pub. No.: US 2011/0210370 A1
(43) Pub. Date: Sep. 1, 2011

(54) Light emitting device

(76) Inventors: Hitoshi Kamamori, Chiba-shi (JP); Keiichiro Hayashi, Chiba-shi (JP); Sadao Oku, Chiba-shi (JP); Hiroyuki Fujita, Chiba-shi (JP); Koji Tsukagoshi, Chiba-shi (JP)

(21) Appl. No.: 12/932,120

(22) Filed: Feb. 17, 2011

(30) Foreign Application Priority Data
Mar. 1, 2010 (JP) 2010-044738

(51) Int. Cl. H01L 33/40

(52) U.S. Cl. 257/99; 257/E33.063

(57) ABSTRACT

On a through-electrode (7) formed by filling a conductive material into a though hole of a substrate, nano-metal particles are adhered to form a connection electrode (9). An LED element (3) is electrically connected to the through-electrode (7) via the connection electrode (9). The nano-metal particles can be applied into a desired shape by an inkjet method or a dispenser method, and hence a light emitting device (1) having high electrical connection reliability is realized at low cost.

### BACKGROUND OF THE INVENTION

1. Field of the Invention

The present invention relates to a light emitting device in which a light emitting element is package-mounted on a substrate having through-electrodes formed therein.

2. Description of the Related Art

Light emitting elements, especially LED elements driven with low voltage and low power consumption, have been improved in emission luminance and emission life and are accordingly used in a wide range of fields, including interior lamps, automobile lighting, and backlights for liquid crystal display elements. In recent years, a glass material is used for a substrate material on which the LED element is mounted. The glass material prevents moisture and contaminants from entering from the outside and has high airtightness. Further, the glass material has a thermal expansion coefficient which approximates that of a silicon substrate for forming the LED element, and hence high reliability is ensured at a mounting surface or at a bonding surface. Besides, because the glass material is inexpensive, an increase in cost of products can be suppressed. However, the glass material is low in radiation performance, and hence when the glass material is heated by heat from the LED element itself, the LED element is lowered in luminance efficiency. It is therefore necessary to adopt a structure for effective radiation.

In view of this, Japanese Patent Application Laid-open No. 2007-42781 (Prior application 1) discloses a structure in which the glass substrate is provided with through-electrodes and the LED elements are mounted on the through-electrodes. FIG. 5 is a cross-sectional view schematically illustrating a light emitting device in which two LED elements are mounted on a glass substrate 14, which corresponds to FIG. 1 of the prior application 1. Three through-electrodes 7 are formed in the flat glass substrate 14. An electrode metallization 13 is provided on each of the through-electrodes 7, and the LED elements 3 are mounted on the electrode metallizations 13 of two of the through-electrodes 7. An application electrode provided on a lower surface of the LED element 3 is electrically connected to the through-electrode via the electrode metallization 13, while an application electrode provided on an upper surface of the LED element 3 is electrically connected to the through-electrode, on which the LED element 3 is not mounted, via the wire 4 and the electrode metallization 13. On a lower surface of the glass substrate 14, terminal electrodes 8 are formed to be electrically connected to the through-electrodes 7. Therefore, the LED element 3 can be supplied with power from the pair of terminal electrodes 8 formed on the lower surface of the glass substrate 14.

On an upper surface of the flat glass substrate 14, a Si substrate 15 having an opening portion 6 formed therein is disposed so as to surround the LED elements 3. The Si substrate 15 is anodically-bonded to the surface of the glass substrate 14. The Si substrate 15 has an inclined inner wall surface, and a reflective film is formed on a surface thereof. Light emitted from the LED elements is reflected by the reflective film, and exits as light with upward directivity. Heat generated by the LED elements is dissipated to the outside via the through-electrodes 7 and the terminal electrodes 8.

Here, in the prior application 1, the through-electrodes 7 are formed in the flat glass substrate 14, and the electrode metallization 13 made of a plurality of metal layers is formed on the surface of each through-electrode 7. The electrode metallization 13 is formed such that the plurality of metal layers are formed on the glass substrate by a sputtering method or a vapor deposition method, and a photolithography process involving etching with a photoresist or a lift-off process is used to obtain a desired shape. After that, the Si substrate 15 having the opening portion 6 formed therein is bonded to the glass substrate 14. Then, the LED elements 3 are mounted and the opening portion 6 is filled with a sealing member 5.

As described above, in the prior application 1, a plurality of metal layers are formed by the sputtering method to manufacture an electrode metallization, and hence the process cost is high. Further, the photolithography process or the lift-off process requires a flat substrate surface, and hence the Si substrate having the opening portion cannot be bonded to the glass substrate before the electrode metallization is formed on the upper surface of the glass substrate. Therefore, a metallization cannot be formed in a structure in which the through-electrode is provided on a bottom part of a recess formed in the surface of the substrate, and there is no choice but to directly bond a wire to the exposed surface of the through-electrode.

### SUMMARY OF THE INVENTION

In order to solve the above-mentioned problems, a light emitting device according to the present specification includes: a substrate including a through-electrode formed therein; a light emitting element electrically connected to the through-electrode; and a connection electrode provided on a surface of the through-electrode exposed from the substrate, the connection electrode being formed of nano-metal particles, in which the light emitting element and the through-electrode are electrically connected to each other via the connection electrode. As the nano-metal particles, one of nano-silver particles, nano-gold particles, nano-copper particles, and a mixture of at least two kinds thereof may be used.

Further, the connection electrode is formed in a range including a surface region, in which the through-electrode is exposed from the substrate, and a peripheral surface region around the surface region. Still further, a wire for connecting the light emitting element and the connection electrode to each other is provided, and the wire is bonded to the peripheral surface region.

Further, the substrate includes a concave portion provided in a surface of the substrate, the concave portion being positioned lower than the surface, the through-electrode is exposed in the concave portion, and the connection electrode is provided in the concave portion.

Further, the light emitting device according to the present specification further includes a first electrode pad and a second electrode pad formed on the light emitting element, for applying a voltage to the light emitting element. And a first through-electrode and a first connection electrode are formed on the substrate corresponding to the first electrode pad, and a second through-electrode and a second connection electrode are formed on the substrate corresponding to the second electrode pad. The first electrode pad and the first connection electrode are connected to each other via a conductive member, and the second electrode pad and the second connection electrode are electrically connected to each other via the wire. Alternatively, the first electrode pad and the first connection electrode may be connected by Au—Sn eutectic bonding, and the second electrode pad and the second connection electrode may be electrically connected to each other via the wire.

Note that, the through-electrode can be formed by filling a conductive material into a through hole opened in the substrate. Further, a sealing material may be supplied to cover the light emitting element. Still further, using a substrate having a shape including a recess, the through-electrode may be formed in the recess, the light emitting element may be placed on a bottom surface of the recess, and the sealing material may be supplied in the recess.

Further, the light emitting element and the connection electrode are connected by a flip-chip bonding method.

### BRIEF DESCRIPTION OF THE DRAWINGS

In the accompanying drawings:

FIGS. 1A and 1B are schematic views illustrating a light emitting device according to a first specific example of the present invention;

FIG. 2 is a schematic view illustrating a cross-sectional structure of a light emitting device according to a second specific example of the present invention;

FIGS. 3A and 3B are schematic views illustrating a light emitting device according to a third specific example of the present invention;

FIGS. 4A and 4B are schematic views illustrating a light-emitting device according to a fourth specific example of the present invention; and

FIG. 5 is a schematic view illustrating a cross-sectional structure of a conventional light emitting device.

### DETAILED DESCRIPTION OF THE PREFERRED EMBODIMENTS

A light emitting device according to the present application has a structure in which a light emitting element is mounted on a substrate having through-electrodes formed therein. On the surface of the through-electrode exposed from the substrate, a connection electrode formed of nano-metal particles is provided. The light emitting element is electrically connected to the through-electrode via the connection electrode. The through-electrode is manufactured by filling a conductive material into a through hole opened in the substrate. In general, a sealing material is provided to cover the light emitting element. This way, the light emitting element and the through-electrode are electrically connected to each other via the connection electrode, which is formed by adhering the nano-metal particles onto the through-electrode. This structure improves connection reliability, as compared with a structure in which the light emitting element is electrically connected to the through-electrode directly.

The nano-metal particles are exemplified by nano-silver particles, nano-gold particles, nano-copper particles, and a mixture of at least two kinds of those particles. Such nano-metal particles can be adhered by an inkjet method or a dispenser method, and hence the connection electrode can be formed into a desired shape without using a patterning method. Even such an inexpensive method provides reliability equivalent to that of a metal film which is formed by an expensive method, such as vacuum deposition and photolithography. Further, because the inkjet method or the dispenser method is used, the connection electrode can easily be formed on a substrate with an uneven surface.

The connection electrode is formed in a range including the surface of the through-electrode exposed from the substrate and a peripheral surface region around the surface. In other words, the connection electrode has a center region, which is positioned directly upon the through-electrode, and a peripheral region around the center region. The area of the connection electrode is therefore larger than the exposed area of the through-electrode. A concave portion may be provided in the surface of the substrate, and the surface of the through-electrode may be exposed from the concave portion. The connection electrode can be provided in the concave portion. In this case, it should be understood that the area of the concave portion is larger than the area of the through-electrode exposed in the concave portion of the substrate. When the light emitting element is electrically connected to the connection electrode via a wire, it is desired that the wire be connected to the peripheral region of the connection electrode.

Alternatively, a substrate having a recess formed therein may be used. The through-electrode is formed in the recess and the light emitting element is disposed on a bottom surface of the recess. The light emitting element and the through-electrode are connected as described above. The recess is supplied with a sealing material to protect the light emitting element. The substrate having a recess is exemplified by a glass substrate which is formed using a glass material in an integral manner. Alternatively, the substrate may be structured by bonding different materials in an integral manner. The nano-metal particles are improved in adhesion to the base at a relatively low temperature during heat treatment, which expands the range of choices for the substrate material. For example, in addition to the glass material, a ceramics material, an aluminum nitride material, a metal material, and a resin material are available.

Hereinbelow, a specific description is given of examples using an LED as the light emitting element and a glass package as the substrate having a recess formed therein.

### FIRST EXAMPLE

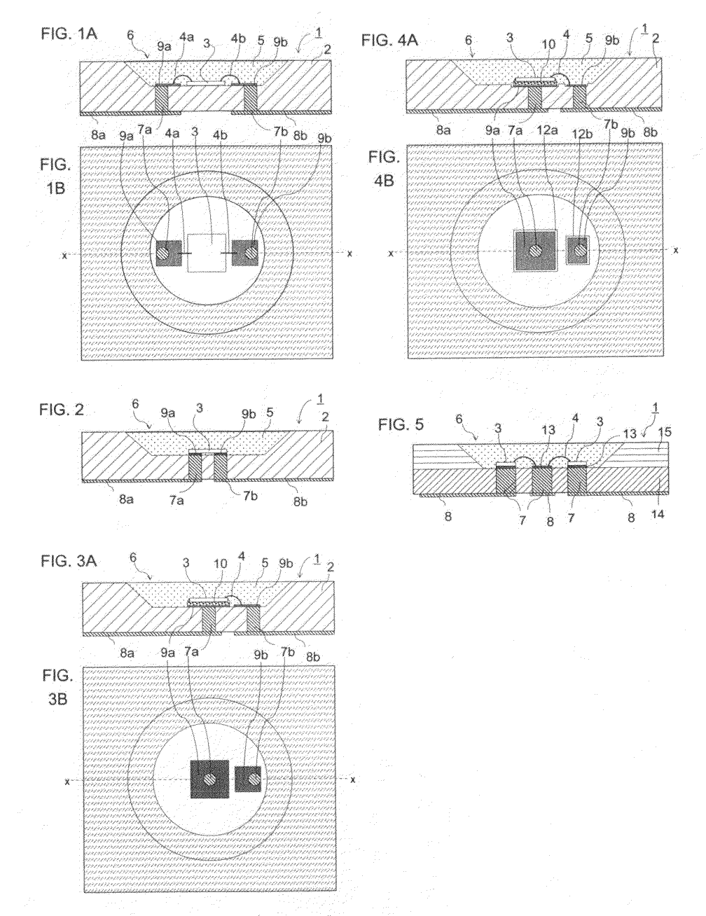

FIGS. 1A and 1B schematically illustrate a light emitting device 1 according to a first example. FIG. 1A is a cross-sectional view schematically illustrating a structure in vertical cross-section, and FIG. 1B is an overhead view of the structure. The light emitting device 1 has a structure in which an LED element 3 is mounted on a bottom part of a recess 6 in a glass package 2 via a die-bonding material (not shown). In the first specific example, the recess 6 is formed in a bottom part of the center of the glass package 2. Through-electrodes 7a and 7b are formed in the glass package 2 to pass therethrough from a bottom surface of the recess 6 to a rear surface of the glass package 2. Terminal electrodes 8a and 8b are formed on the rear surface of the glass package 2, and connected to the through-electrodes 7a and 7b. On the bottom surface of the recess 6, connection electrodes 9a and 9b are formed by adhering nano-metal particles in regions including exposed parts of the through-electrodes 7a and 7b. In other words, the connection electrode 9a or 9b includes a center region positioned directly upon the through-electrode, and a peripheral region around the center region. The respective area of the each connection electrode is therefore larger than the area of the through-electrode. Note that, the through-electrodes 7a and 7b cannot be directly seen in practice when viewing the light emitting device 1 from overhead because the through-electrodes 7a and 7b are positioned below the connection electrodes 9a and 9b, but are illustrated for convenience of description.

On the upper part of the LED element 3, a pair of electrode pads (not shown) are formed, and the pair of electrode pads are electrically connected to the connection electrodes 9a and 9b via wires 4a and 4b, respectively. In this case, the wires are each bonded to the peripheral region of the connection electrodes, rather than being bonded directly above the center region. This structure enables voltage supply between the terminal electrodes so that the LED element emits light.

The nano-metal particles as used herein are metal particles having a diameter of several nm to several tens of nm. For example, nano-silver particles are dispersed in a binder resin and subjected to printing by an inkjet printing method or the like. The nano-silver particles dispersed in the solvent are jetted from nozzles of an inkjet printer. The large number of nozzles are arrayed and move relative to the glass package 2, to thereby perform planar printing. Liquid droplets jetted from the nozzles are discharged by an extremely trace amount in the form of a bullet. Printing can be performed with a fixed distance of 2 mm to 3 mm between a tip of the nozzle and a printing surface. Therefore, it is possible to print a predetermined micropattern even for printing on an uneven surface. After the printing, heat treatment is carried out at 100° C. to 500° C. This way, a connection electrode having good adhesion to the glass package and the through-electrode can be formed. Printing and metallizing normal silver particles require heat treatment at 1,000° C. or higher, but the use of nano-silver particles can provide good adhesion with low-temperature heat treatment because the particles are large in surface area and high in reactivity. Further, patterning by a photoprocess is not required, and hence a manufacturing process can be simplified to reduce manufacturing cost of the light emitting device 1.

In the first example, the glass package 2 employs a plate-like glass material, and the recess 6 and a hole for the through-electrode are formed by molding. The glass package 2 is formed in an integral manner and thus no bonding portion of different materials is formed, and hence durability is improved. The recess 6 and the hole for the through-electrode are formed by molding, but may be formed by a sandblasting method or an etching method instead. Further, in order to reflect light emitted from the LED element 3, an optical reflective film may be formed on a side surface and the bottom surface of the recess 6 in the glass package 2.

The through-electrode can be formed by filling and hardening a conductive paste containing Ag into a through hole provided in the bottom part of the recess 6 in the glass package 2. Alternatively, the through-electrode may be formed such that a metal material such as Kovar, Ni, Fe, or Cu is filled instead of the conductive paste or together with the conductive paste and is then heated and hardened. Further, a metal core can be inserted for bonding and fixation. The through-electrode can also be formed such that melted solder is filled and is then cooled and hardened.

The LED element 3 is mounted on the glass package 2 via the die-bonding material (not shown). The electrode pads (not shown), which are formed on the surface of the LED element 3, and the through-electrodes 7a and 7b are electrically connected via the wires 4a and 4b made of Au, respectively. The LED element 3 and the wires 4a and 4b are sealed by a sealing material 5. A transparent resin material may be used as the sealing material 5. Alternatively, a metal oxide which is obtained by polymerizing and firing a metal alkoxide or a polymetalloxane formed from a metal alkoxide may be used. In particular the case where a metal oxide which is formed from a metal alkoxide or a polymetalloxane is used as the sealing material 5, a thermal expansion coefficient of the sealing material 5 approximates that of the package 2 made of glass because the package 2 is also a silicon oxide, with the result that good adhesion and sealing performance are obtained.

The terminal electrodes 8a and 8b can be formed by a vapor deposition method or a sputtering method with a metal, or a printing method with a conductive material. In the printing method, the deposition of a conductive film and its patterning are performed at a time to simplify the manufacturing process. When the terminal electrodes are formed on the glass package 2 by vapor deposition or sputtering with a metal, it is desired to form a Ti layer for enhancing the adhesion, a barrier layer thereon, a Pt layer or a Ni layer thereon, and a Au layer for preventing surface oxidation. Further, the terminal electrode may be formed by a lift-off method, in which an electrode pattern is formed in advance by a photosensitive resin, such as a resist, and a metal film is deposited thereon, followed by removing the resist. Still further, the terminal electrode may be formed using a lead frame.

### SECOND EXAMPLE

FIG. 2 schematically illustrates a vertical cross-sectional view of a light emitting device 1 according to a second example. The second example differs from the first example in that the LED element 3 and the connection electrodes 9a and 9b are connected by a flip-chip bonding method. Other structures are the same as those in the first example, and hence overlapping description is omitted as appropriate.

On the bottom part of the recess 6 in the glass package 2, the through-electrodes 7a and 7b are formed to pass through the glass package 2 from the bottom surface of the recess 6 to the rear surface of the glass package 2. The connection electrodes 9a and 9b are formed by adhering nano-metal particles onto exposed parts of the through-electrodes 7a and 7b on the bottom surface of the recess 6. The electrode pads formed on the LED element are connected to the connection electrodes. The terminal electrodes 8a and 8b electrically connected to the through-electrodes 7a and 7b, respectively, are provided on the rear surface of the glass package 2.

### THIRD EXAMPLE

FIG. 3A schematically illustrates a vertical cross-sectional view of a light emitting device 1 according to a third example. The third example differs from the first example in that one of the terminal pads of the LED element 3 is connected to the connection electrode 9a or 9b face-down and the other is connected via a wire. Other structures are the same as those in the first example, and hence overlapping description is omitted as appropriate.

FIG. 3A is a cross-sectional view schematically illustrating a structure of the light emitting device 1, and FIG. 3B is a top view thereof before the LED element 3 is mounted. In the recess 6 in the center of the glass package 2, the through-electrodes 7a and 7b are formed to pass through the glass package 2 from the bottom surface of the recess 6 to the rear surface of the glass package 2. The connection. electrodes 9a and 9b are formed by adhering nano-metal particles in regions including exposed parts of the through-electrodes 7a and 7b. In other words, the connection electrode 9a or 9b includes a center region positioned directly upon the through-electrode, and a peripheral region around the center region. The respective area of the each connection electrode is therefore larger than the area of the through-electrode. A pair of electrode pads (not shown) are formed on the LED element 3, and one of the electrode pads is connected to the connection electrode 9a via a conductive member 10, and the other electrode pad is electrically connected to the connection electrode 9b via a wire 4. In this case, the wire 4 is bonded to the surface of the peripheral region, rather than being bonded to the surface of the center region.

The one electrode pad may be connected to the connection electrode 9a by a method of Au—Sn eutectic bonding, instead of the conductive member 10.

### FOURTH EXAMPLE

FIGS. 4A and 4B schematically illustrate a structure of a light emitting device 1 according to a fourth example. The fourth example differs from the third example in that the connection electrodes 9a and 9b are each provided in a concave portion formed in the recess 6 of the glass package 2. Other structures are the same as in the third example, and hence overlapping description is omitted as appropriate. FIG. 4A is a cross-sectional view schematically illustrating the structure of the light emitting device 1, and FIG. 4B is a top view thereof before the LED element 3 is mounted. As illustrated in FIGS. 4A and 4B, the concave portions are formed in the bottom surface of the recess 6 in the glass package 2. In other words, the bottom surface of each concave portion is positioned lower than the bottom surface of the recess 6. The through-electrode and the connection electrode are formed in the concave portion. The through-electrode 7a is formed to be exposed on a bottom surface of a concave portion 12a. The connection electrode 9a is provided in the concave portion 12a. The LED element 3 is connected to the connection electrode 9a via the conductive member 10. The area of the concave portion 12a is larger than the exposed area of the through-electrode 7a, and the concave portion 12a is larger than the LED element 3. Further, the through-electrode 7b is formed to be exposed from a bottom surface of a concave portion 12b, and the connection electrode 9b is provided in the concave portion 12b. The area of the concave portion 12b is larger than the exposed area of the through-electrode 7b. An electrode pad (not shown) formed on the upper surface of the LED element 3 is electrically connected to the connection electrode 9b via the wire 4. In this case, the wire 4 is bonded to a part of the connection electrode 9b not directly above the through-electrode 7b.

As described above, the connection electrodes 9a and 9b can be formed inside the concave portions 12a and 12b, respectively, by applying nano-metal particles using an inkjet method or a dispenser method. By laying out an applying portion with the concave portion in advance, the application position accuracy can be increased.

What is claimed is:

1. A light emitting device, comprising:
a substrate including a through-electrode formed therein;
a light emitting element mounted on the substrate and electrically connected to the through-electrode; and
a connection electrode provided on a surface of the through-electrode exposed from the substrate, the connection electrode being formed of nano-metal particles,
wherein the light emitting element and the through-electrode are electrically connected to each other via the connection electrode.

2. A light emitting device according to claim 1, wherein the nano-metal particles comprise one of nano-silver particles, nano-gold particles, nano-copper particles, and a mixture of at least two kinds thereof.

3. A light emitting device according to claim 1, wherein:
the connection electrode has a surface area larger than a surface area of the through-electrode exposed from the substrate; and
the connection electrode includes a face-to-face region, which is positioned directly on the through-electrode, and a peripheral region around the face-to-face region.

4. A light emitting device according to claim 3, wherein:
the substrate comprises a concave portion provided in a surface of the substrate, the concave portion being positioned lower than the surface;
the through-electrode is exposed in the concave portion; and
the connection electrode is provided in the concave portion.

5. A light emitting device according to claim 3, further comprising a wire for connecting the light emitting element and the connection electrode to each other,
wherein the wire is bonded to the peripheral region.

6. A light emitting device according to claim 5, further comprising a first application electrode and a second application electrode formed on the light emitting element, for applying a voltage to the light emitting element,
wherein the through-electrode and the connection electrode comprise a first through-electrode and a first connection electrode corresponding to the first application electrode, and a second through-electrode and a second connection electrode corresponding to the second application electrode, and
wherein the first application electrode is connected to the first connection electrode via a conductive member, and the second application electrode and the second connection electrode are electrically connected to each other via the wire.

7. A light emitting device according to claim 5, further comprising a first application electrode and a second application electrode formed on the light emitting element, for applying a voltage to the light emitting element,
wherein the through-electrode and the connection electrode comprise a first through-electrode and a first connection electrode corresponding to the first application electrode, and a second through-electrode and a second connection electrode corresponding to the second application electrode, and
wherein the first application electrode and the first connection electrode are connected by Au—Sn eutectic bonding, and the second application electrode and the second connection electrode are electrically connected to each other via the wire.

8. A light emitting device according to claim 1, wherein the through-electrode has a structure in which a conductive material is filled into a through hole opened in the substrate.

9. A light emitting device according to claim 8, further comprising a sealing material supplied to cover the light emitting element.

10. A light emitting device according to claim 9, wherein:
the substrate has a shape including a recess;
the through-electrode is formed in the recess;
the light emitting element is placed on a bottom surface of the recess; and
the sealing material is supplied in the recess.

11. A light emitting device according to claim 1, wherein the light emitting element and the connection electrode are connected by a flip-chip bonding method.
